(19) United States
(12) Patent Application Publication
(10) Pub. No.: US 2024/0004405 A1
(43) Pub. Date: Jan. 4, 2024

(54) BATTERY MONITORING METHOD, BATTERY AND UNMANNED AERIAL VEHICLE

(71) Applicant: Autel Robotics., LTD., Shenzhen (CN)

(72) Inventor: Wei QIN, Shenzhen (CN)

(73) Assignee: Autel Robotics., LTD., Shenzhen (CN)

(21) Appl. No.: 18/369,823

(22) Filed: Sep. 18, 2023

Related U.S. Application Data
(63) Continuation of application No. PCT/CN22/79351, filed on Mar. 4, 2022.

(30) Foreign Application Priority Data
Mar. 19, 2021 (CN) 2021102962256

(51) Int. Cl. G05D 1/10; G01R 31/382; G08B 21/18; B60L 58/10; B64D 27/24; B64U 50/30

(52) U.S. Cl. CPC G05D 1/102; G01R 31/382; G08B 21/187; B60L 58/10; B64D 27/24; B64U 50/30; B60L 2200/10

(57) ABSTRACT

A battery is detachably mounted on an unmanned aerial vehicle by using at least one attachment mechanism. The battery monitoring method includes: detecting, by the battery, before the unmanned aerial vehicle takes off, whether the at least one attachment mechanism is in place; and sending, by the battery, a first signal to the flight control system in response to detecting that the at least one attachment mechanism is in place, wherein the first signal is configured to instruct the flight control system to initiate takeoff of the unmanned aerial vehicle; or sending, by the battery, a second signal to the flight control system in response to detecting that at least one of the at least one attachment mechanism is not in place, wherein the second signal is configured to instruct the flight control system to prevent takeoff of the unmanned aerial vehicle.

### CROSS-REFERENCE TO RELATED APPLICATION

The present application is a Continuation Application of International Application No. PCT/CN2022/079351, filed on Mar. 4, 2022, which claims the benefit of priority to Chinese patent Application No. 2021102962256, filed on Mar. 19, 2021, both disclosures of which are incorporated by references herein for all purposes.

### BACKGROUND

An unmanned aerial vehicle (“UAV”) is an unmanned aircraft that controls a flight attitude by using a radio remote control device and a built-in program. Since the unmanned aerial vehicle has advantages such as high maneuverability, quick response, unmanned driving and low operation requirements, the unmanned aerial vehicle has been widely used in various fields such as aerial photography, plant protection, power inspection and disaster relief. The unmanned aerial vehicles are generally equipped with a plurality of airborne detachable batteries.

### SUMMARY

The present disclosure relates to the field of unmanned aerial vehicles, and more specifically, to a battery monitoring method, a battery and an unmanned aerial vehicle. In order to overcome the problems existing in the related technologies, the present disclosure provides a battery monitoring method, a battery and an unmanned aerial vehicle.

According to a first aspect of the present disclosure, there is provided a battery monitoring method. The battery is detachably mounted in an unmanned aerial vehicle by using at least one attachment mechanism, and the battery is communicatively connected to a flight control system of the unmanned aerial vehicle. The method includes: detecting, by the battery, before the unmanned aerial vehicle takes off, whether the at least one attachment mechanism is in place; and sending, by the battery, a first signal to the flight control system in response to detecting that the at least one attachment mechanism is in place, wherein the first signal is configured to instruct the flight control system to initiate takeoff of the unmanned aerial vehicle; or sending, by the battery, a second signal to the flight control system in response to detecting that at least one of the at least one attachment mechanism is not in place, wherein the second signal is configured to instruct the flight control system to prevent takeoff of the unmanned aerial vehicle.

According to a second aspect of the present disclosure, there is provided a battery, including: a battery body; a signal monitor, connected to the battery body, wherein the signal monitor is configured to obtain a mount signal of at least one attachment mechanism, wherein the at least one attachment mechanism is configured to detachably mount the battery on an unmanned aerial vehicle, wherein the mount signal is configured to indicate whether the at least one attachment mechanism is in place; a processor, respectively connected to the signal monitor and the battery body, wherein the processor is configured to be communicatively connected to a flight control system of the unmanned aerial vehicle; and a memory, connected to the processor, wherein the memory stores instructions executable by the processor; wherein the instructions is executed by the processor to enable the processor to perform the method according to the first aspect of the present disclosure.

According to a third aspect of the present disclosure, there is provided an unmanned aerial vehicle, including a flight control system and the battery according to the second aspect of the present disclosure.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the description, illustrate embodiments consistent with the present disclosure and, together with the description, serve to explain the principles of the present disclosure.

FIG. 1A is a schematic diagram of an unmanned aerial vehicle according to an embodiment of the present disclosure.

FIG. 1B is a schematic diagram of an unmanned aerial vehicle according to an embodiment of the present disclosure.

FIG. 2 is a schematic diagram of a battery according to an embodiment of the present disclosure.

FIG. 3 is a schematic diagram of a signal monitor in the battery shown in FIG. 2.

FIG. 4 is a schematic diagram of a signal monitor in the battery shown in FIG. 2.

FIG. 5 is a flowchart of a battery monitoring method according to an embodiment of the present disclosure.

FIG. 6 is a flowchart of a battery monitoring method according to an embodiment of the present disclosure.

### DETAILED DESCRIPTION

The present disclosure is described in detail below with reference to specific embodiments. The following embodiments will help a person skilled in the art to further understand the present disclosure, but are not intended to limit the present disclosure in any form. It should be noted that, a person of ordinary skill in the art may further make some variations and improvements without departing from the concept of the present disclosure. The variations and improvements belong to the protection scope of the present disclosure.

To make the objectives, technical solutions, and advantages of the present disclosure clearer and more understandable, the present disclosure is further described in detail below with reference to the accompanying drawings and the embodiments. It is to be understood that specific embodiments described herein are merely used to describe the present disclosure, but are not intended to limit the present disclosure.

It is to be noted that, if no conflict occurs, features in the embodiments of the present disclosure may be combined with each other and fall within the protection scope of the present disclosure. In addition, although functional module division is performed in the schematic diagram of the apparatus, and a logical sequence is shown in the flowchart, in some cases, the shown or described steps may be performed by using module division different from the module division in the apparatus, or in a sequence different from the sequence in the flowchart. In addition, words such as “first”, “second” and “third” used in this specification do not limit data or an execution order, but are only used to distinguish same objects or similar objects whose functions and purposes are basically the same.

Unless otherwise defined, meanings of all technical and scientific terms used in this specification are the same as that usually understood by a person skilled in the technical field to which the present disclosure belongs. Terms used in the specification of the present disclosure are merely intended to describe objectives of the specific implementations, and are not intended to limit the present disclosure. A term “and/or” used in this specification includes any or all combinations of one or more related listed items.

In addition, technical features involved in implementations of the present disclosure that are described below may be combined with each other as long as no conflict occurs.

The unmanned aerial vehicles are generally equipped with a plurality of airborne detachable batteries. The detachable batteries are easy to replace and recharge. However, a problem of battery falling off often occurs during flight, which is likely to cause an exploding accident. Once such an accident occurs, it will not only cause property losses to a user, but also not be conducive to analyzing and locating the problem by a manufacturer. In view of this, to avoid occurrence of such an accident and also to accurately locate the cause of the accident, it is necessary for a person skilled in the art to resolve the problem of battery falling off.

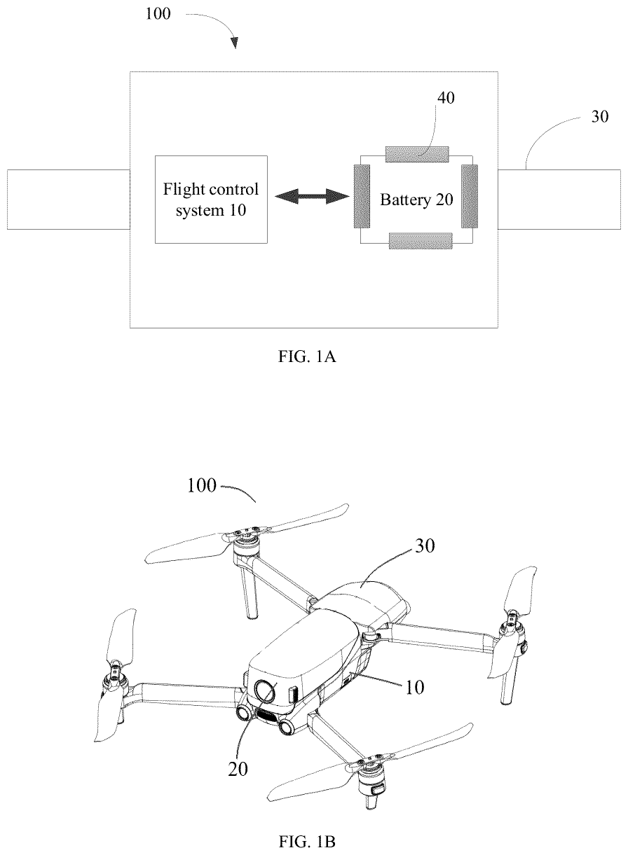

Referring to FIG. 1A, a first embodiment of the present disclosure provides an unmanned aerial vehicle 100, including a flight control system 10, a battery 20 and a vehicle body 30. The battery 20 is detachably mounted on the vehicle body 30 of the unmanned aerial vehicle by using at least one attachment mechanism 40. In addition, the battery 20 is communicatively connected to the flight control system 10.

The flight control system 10 is the core system of the unmanned aerial vehicle during the entire flight process such as completing takeoff, flying in the air, executing the mission and returning to the field for recovery and the like, and is equivalent to the pilot of the unmanned aerial vehicle, The flight control system 10 generally includes three parts, namely, a sensor component, a flight control computer and a servo actuating device. Three main functions are implemented, namely, attitude stabilization and control for the unmanned aerial vehicle, mission device management for the unmanned aerial vehicle and emergency control.

The sensor component mainly includes a gyroscope (flight attitude perception), an accelerometer, a geomagnetic sensor, a barometric pressure sensor (rough control of a hovering height), an ultrasonic sensor (precise control of a low altitude or obstacle avoidance), an optical flow sensor (precise determining of a hovering horizontal position), a GPS module (rough positioning of a horizontal position height), a control circuit and the like. Each sensor is connected to the flight control computer. The flight control computer receives a signal of the sensor and controls, based on the signal, the unmanned aerial vehicle to fly.

It may be understood that, the flight control computer mainly includes hardware such as a main processing controller, a secondary power supply, an input/output interface, a communication interface and a detection interface, which are integrated in a chassis. The flight control computer is combined with flight control software, generates instructions based on signals of sensors, and cooperates with the servo actuating device to implement flight control of the unmanned aerial vehicle.

Mainly based on the instructions of the flight control computer and according to specified static and dynamic requirements, the servo actuating device implements flight control of the unmanned aerial vehicle by controlling control surfaces and dampers in the vehicle body of the unmanned aerial vehicle.

The battery 20 is a rechargeable lithium battery (a lithium ion or a polymer battery). In the present disclosure, the battery 20 is a battery that can perform data communication, for example, a data communication battery, which is communicatively connected to the flight control system. In some embodiments, the battery 20 includes a communication port and is in a wired communication connection with a communication interface of the flight control system by using the communication port, to implement data communication. It may be understood that, in some other embodiments, the battery 20 has a wireless communication module, for example, Bluetooth, a local area network or the like. The battery 20 is in wireless communication connection with the flight control system 10. In the present disclosure, a communication connection manner for the battery 20 is not limited, as long as the battery 20 can perform data communication with the flight control system 10.

The battery 20 is detachably mounted on the vehicle body 30 of the unmanned aerial vehicle 100 by using at least one attachment mechanism 40, to supply power to the unmanned aerial vehicle 100. In some embodiments, the attachment mechanism 40 may include a locking structure such as a buckle, a lock catch, fasteners, clamps, pins, snap-fits, hooks, interlocking joints, or the like. For example, the battery 20 is mounted on the unmanned aerial vehicle by using four buckles. By fixing by using the four buckles, the battery 20 can be prevented from falling off due to drastic flight changes during flight of the unmanned aerial vehicle 100. When the battery 20 is to be charged, the buckles are opened, so that the battery 20 is removed and replaced with a new battery. It may be understood that the new battery also matches the buckles.

Any attachment mechanism 40 may have a problem that the attachment mechanism cannot be mounted in place due to damage, aging or improper mounting. As a result, the battery 20 is likely to fall off, causing an exploding accident. To effectively prevent the accident caused by falling off of the battery 20, the battery 20 can detect whether each attachment mechanism 40 is mounted in place, to monitor mounting stability of the battery 20, so that a monitoring result can be sent to the flight control system 10. The flight control system 10 controls a flight status of the unmanned aerial vehicle 100 based on the monitoring result, which can effectively avoid the exploding accident caused by falling off of the battery 20 and ensure safety of the unmanned aerial vehicle 100.

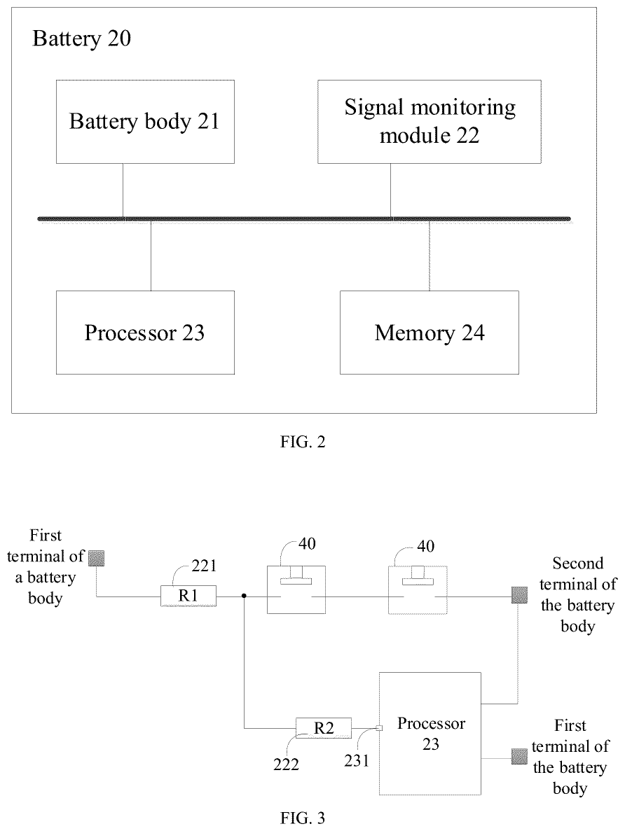

Referring to FIG. 2, a second embodiment of the present disclosure provides a battery 20. The battery 20 may be used as the battery of the unmanned aerial vehicle in the first embodiment. The battery 20 provided in the second embodiment of the present disclosure includes a battery body 21, a signal monitor 22, a processor 23 and a memory 24. The battery body 21 is a lithium battery and is configured to supply power to the signal monitor 22, the processor 23 and the unmanned aerial vehicle. The battery 20 is detachably mounted on the unmanned aerial vehicle by using at least one attachment mechanism.

The signal monitor 22 is connected to the battery body 21. The signal monitor 22 is configured to acquire a mount signal of the at least one attachment mechanism. The mount signal is used for reflecting whether the at least one attachment mechanism is mounted in place. For example, when the battery is detachably mounted on the unmanned aerial vehicle by using four attachment mechanisms. The mount signal reflects whether all the four attachment mechanisms are mounted in place. If all the four attachment mechanisms are mounted in place, the mount signal is in a first state, the first state representing that all the four attachment mechanisms are mounted in place. If there are one or more attachment mechanisms that are not mounted in place, the mount signal is in a second state, the second state representing that there is an attachment mechanism that is not mounted in place.

As shown in FIG. 3, in some embodiments, the signal monitor 22 includes a first resistor 221, the first resistor 221 and each attachment mechanism 40 in the at least one attachment mechanism forming a first series circuit, the first series circuit breaks when one attachment mechanism is not mounted in place. A first terminal of the first series circuit is connected to a first terminal of the battery body, a second terminal of the first series circuit is connected to a second terminal of the battery body, a first terminal of the first resistor is connected to the first terminal of the first series circuit and a second terminal of the first resistor is connected to a first port 231 of the processor 23.

The first terminal of the battery body may be a positive electrode and the second terminal of the battery body is a negative electrode. Correspondingly, the first terminal of the battery body may be a negative electrode and the second terminal of the battery body is a positive electrode. For example, descriptions are provided below by using an example in which the first terminal of the battery body is a positive electrode and the second terminal of the battery body is a negative electrode.

It may be understood that, when each attachment mechanism 40 is mounted in place, the first series circuit is conducted, and the first resistor 221 provides a current-limiting function, to prevent a short circuit. A voltage of a second terminal of the first resistor 221 is a voltage of the negative electrode of the battery body. In this case, a signal inputted into the first port 231 of the processor 23 is at a low level, so that a mount signal acquired by using the first port 231 is at a low level, which indicates that each attachment mechanism is mounted in place. When one attachment mechanism is not mounted in place, the first series circuit will generate a break. The voltage of the second terminal of the first resistor 221 is a voltage of the positive electrode of the battery body. In this case, a signal inputted into the first port 231 is a high-level signal, which indicates that there is an attachment mechanism that is not mounted in place. In other words, in this embodiment, the mount signal is a level signal, and whether each attachment mechanism is mounted in place is determined based on a level of the level signal.

It may be understood that, when the first terminal of the battery body is a negative electrode and the second terminal of the battery body is a positive electrode, if the mount signal is a high-level signal, it indicates that each attachment mechanism is mounted in place; and if the mount signal is a low-level signal, it indicates that there is an attachment mechanism that is not mounted in place.

It may be understood that, in some embodiments, each attachment mechanism is locked (mounted in place) by pressing buttons, so that the first series circuit is conducted. In other embodiments, each attachment mechanism is locked in another manner (bolting), so that the first series circuit is conducted. In the present disclosure, a manner of mounting each attachment mechanism in place is not limited, as long as each attachment mechanism is locked (mounted in place).

To prevent a high-level signal inputted into the first port 231 of the processor 23 from being excessively high and causing damage to the processor, in some embodiments, the signal monitor 22 further includes a second resistor 222. A first terminal of the second resistor 222 is connected to the second terminal of the first resistor 221 and a second terminal of the second resistor 222 is connected to the first port 231 of the processor 23, thus providing a voltage division function.

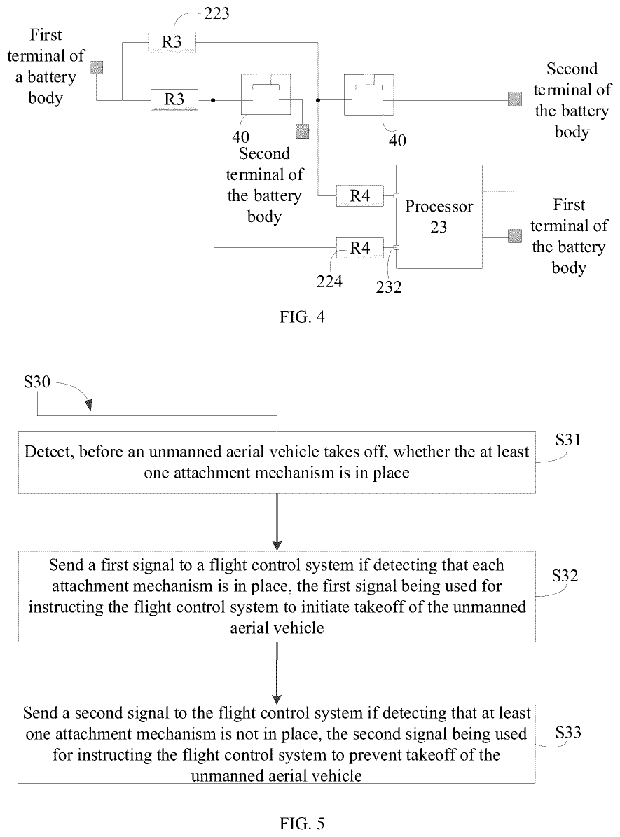

It may be understood that the signal monitor also has other implementations. As shown in FIG. 4, in some embodiments, the signal monitor 22 includes a plurality of third resistors 223 having a same quantity as attachment mechanisms. One third resistor 223 and one attachment mechanism 40 form a second series circuit. When one attachment mechanism is not mounted in place, a corresponding second series circuit is open circuited. A first terminal of each second series circuit is connected to the first terminal of the battery body and a second terminal of each second series circuit is connected to the second terminal of the battery body. In addition, a first terminal of each third resistor 223 is connected to a first terminal of a corresponding second series circuit and a second terminal of each third resistor 223 is connected to a corresponding second port 232 of the processor 23.

When each attachment mechanism is mounted in place, each second series circuit is conducted, and each third resistor 223 provides a current-limiting function, to prevent a short circuit. Any second series circuit 1# is used as an example, and examples are provided below by using an example in which the first terminal of the battery body is a positive electrode and the second terminal of the battery body is a negative electrode. When the second series circuit 1# is conducted, a voltage of a second terminal of the third resistor 1# is the voltage of the negative electrode of the battery body. In this case, a signal inputted into a second port 1# of the processor is at a low level, so that a mount sub-signal 1# acquired by the second port 1# is at a low level, which indicates that a corresponding attachment mechanism 1# is mounted in place. When the attachment mechanism 1# is not mounted in place, the second series circuit is open circuited, and a voltage of a second terminal of the third resistor 223 is the voltage of the positive electrode of the battery body. In this case, a signal inputted into the second port 1# is a high-level signal.

Based on parallel connection of second series circuits including attachment mechanisms, in this embodiment, the mount signal includes mount sub-signals having a same quantity as the attachment mechanisms. When each mount sub-signal is a low-level signal, it indicates that each attachment mechanism is mounted in place. If a mount sub-signal is a high-level signal, it indicates that a corresponding attachment mechanism is not mounted in place.

Similarly, to prevent a high-level signal inputted into each second port of the processor from being excessively high and causing damage to the processor, in some embodiments, the signal monitor 22 further includes a plurality of fourth resistors 224 having a same quantity as attachment mechanisms. A first terminal of one fourth resistor 224 is connected to a second terminal of one third resistor 223 and a second terminal of the fourth resistor 224 is connected to a corresponding second port 232 of the processor 23.

It may be understood that, when the first terminal of the battery body is a negative electrode and the second terminal of the battery body is a positive electrode, if the mount sub-signal is a high-level signal, it indicates that a corresponding attachment mechanism is mounted in place; and if the mount sub-signal is a low-level signal, it indicates that a corresponding attachment mechanism is not mounted in place.

The processor 23 is respectively connected to the signal monitor 22 and the battery body 21. In this way, the processor 23 can receive a mount signal generated by the signal monitor 22. In addition, the battery body 21 can supply power to the processor 23. The processor 23 is further configured to be communicatively connected to the flight control system of the unmanned aerial vehicle, so that the flight control system can perform a corresponding task based on instructions of the processor, for example, controlling a flight status of the unmanned aerial vehicle.

The processor is communicatively connected to a memory. In FIG. 2, a bus connection and one processor are taken as examples for schematic description.

It may be understood that, the processor 23 may be a general-purpose processor, including a central processing unit (CPU), a network processor (NP) and the like. Alternatively, the processor may be a digital signal processor (DSP), an application-specific integrated circuit (ASIC), a field-programmable gate array (FPGA) or another programmable logic device, a discrete gate or a transistor logic device, or a discrete hardware component.

As a non-transitory computer-readable storage medium, the memory 24 may be configured to store a non-transitory software program, a non-transitory computer executable program and a module, such as program instructions/module corresponding to the battery monitoring method in the embodiments of the present disclosure. The processor 23 runs the non-transitory software program, the instructions and the module stored in the memory 24, to implement a battery monitoring method in any of method embodiments below. Specifically, the memory 24 may include a high-speed random access memory, and may further include a non-transitory memory, such as at least one magnetic disk memory device, a flash memory device or another non-transitory solid-state memory device.

A battery monitoring method provided in a third embodiment of the present disclosure is described in detail below. The method may be performed by the processor of the battery in the second embodiment.

Referring to FIG. 5, S30 may include but is not limited to the following steps:
S31: Detect, before an unmanned aerial vehicle takes off, whether the at least one attachment mechanism is in place.
S32: Send a first signal to a flight control system if detecting that each attachment mechanism is in place, the first signal being used for instructing the flight control system to initiate takeoff of the unmanned aerial vehicle.
S33: Send a second signal to the flight control system if detecting at least one attachment mechanism that is not in place, the second signal being used for instructing the flight control system to prevent takeoff of the unmanned aerial vehicle.

For example, the battery is detachably mounted on the unmanned aerial vehicle by using four lock catches (attachment mechanisms). Before the unmanned aerial vehicle takes off, whether the four lock catches are all mounted in place is detected. A specific detection manner can be implemented by using the signal monitor in the second embodiment or may be implemented in another manner, for example, may be detected by using a pressure sensor. This is not limited herein.

A first signal is sent to the flight control system if the four attachment mechanisms are mounted in place, the first signal being used for instructing the flight control system to control the unmanned aerial vehicle to normally take off. A second signal is sent to the flight control system if it is detected that one of the four lock catches is not mounted in place, the second signal being used for instructing the flight control system to control the unmanned aerial vehicle to prohibit takeoff, to remind the user to detect and re-mount each lock catch before takeoff. In this way, before the takeoff, the problem of battery falling off can be effectively monitored, to avoid accidents caused by battery falling off, thus ensuring safety of the unmanned aerial vehicle.

In this embodiment, the battery is detachably mounted by using at least one attachment mechanism, so that the battery can be well fixed even if the attachment mechanism may have a problem that the attachment mechanism cannot be mounted in place due to damage, aging or improper mounting. Before takeoff, each attachment mechanism is detected, and the unmanned aerial vehicle is controlled to normally take off when the attachment mechanism is mounted in place, or otherwise, the takeoff is prohibited. In this way, a problem of battery falling off can be effectively monitored, accidents caused by battery falling off are avoided, and safety of the unmanned aerial vehicle is ensured.

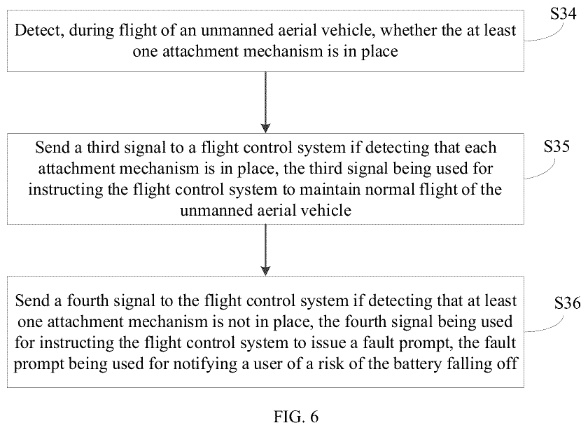

In some embodiments, referring to FIG. 6, S30 further includes the following steps:
S34: Detect, during flight of an unmanned aerial vehicle, whether the at least one attachment mechanism is in place.
S35: Send a third signal to a flight control system if detecting that each attachment mechanism is in place, the third signal being used for instructing the flight control system to maintain normal flight of the unmanned aerial vehicle.
S36: Send a fourth signal to the flight control system if detecting at least one attachment mechanism that is not mounted in place, the fourth signal being used for instructing the flight control system to issue a fault prompt, the fault prompt being used for notifying a user of a risk of the battery falling off.

During flight of the unmanned aerial vehicle, there is also a problem that an attachment mechanism is not mounted in place. If measures are not taken in time, there may be a hidden danger of exploding accidents. To avoid this hidden danger, during the flight of the unmanned aerial vehicle, all attachment mechanisms are detected to detect whether the attachment mechanisms are mounted in place. It may be understood that, the detection may be real-time detection or detection at a preset frequency, and a specific detection manner is the same as that in the foregoing embodiment. This is not repeated herein.

For example, the battery is detachably mounted on the unmanned aerial vehicle by using four lock catches (attachment mechanisms). During flight of the unmanned aerial vehicle, if it is detected that the four lock catches are all mounted in place, a third signal is sent to the flight control system, to instruct the flight control system to control the unmanned aerial vehicle to maintain normal flight. If it is detected that one of the four lock catches is not mounted in place, a fourth signal is sent to the flight control system, to instruct the flight control system to issue a fault prompt, thus notifying the user that the battery has a risk of falling off. In other words, during flight, a problem of battery falling off is monitored. When there is a risk of falling off, a fault prompt is issued in time to remind the user to take a timely measure to avoid accidents.

In this embodiment, each attachment mechanism is detected when the unmanned aerial vehicle takes off. When there is an attachment mechanism that is not mounted in place, a fault prompt is issued by using the flight control system, to notify the user that the battery has a risk of falling off. In this way, the user may take a timely measure, for example, grounding detection, thus avoiding accidents caused by battery falling off.

To further ensure safety of the unmanned aerial vehicle, in some embodiments, the fourth signal is further used for instructing the flight control system to control the unmanned aerial vehicle to make forced landing. It may be understood that, when at least one attachment mechanism that is not mounted in place is detected, it indicates that the battery has a risk of falling off. In this case, the fourth signal is used to instruct the flight control system to control the unmanned aerial vehicle to make forced landing, which can minimize a risk of exploding the unmanned aerial vehicle due to battery falling off. After the unmanned aerial vehicle is controlled to make forced landing, the user may re-mount an attachment mechanism that is not mounted in place, perform maintenance and replacement or the like.

In some embodiments, the flight control system is communicatively connected to a mobile terminal, and the fourth signal is further used for instructing the flight control system to send the fault prompt to the mobile terminal, to prompt the user by using the mobile terminal. It may be understood that the mobile terminal may be a remote controller, a mobile phone or the like. When the unmanned aerial vehicle flies in the air, a mobile terminal such as a remote control or a mobile phone beside the user is used to prompt the user, which can more intuitively and quickly notify the user that there is a risk of battery falling off, and is also convenient for the user to control, by using the mobile terminal, the unmanned aerial vehicle to make landing in time.

In some embodiments, the method further includes the following steps:

S37: Store fault information when detecting at least one attachment mechanism that is not in place, the fault information including identity information of the attachment mechanism that is not in place.

For example, when an attachment mechanism a and an attachment mechanism b that are not mounted in place are detected, in this case, identity information of the attachment mechanism a and the attachment mechanism b are used as the fault information for storage, to provide data support when the user subsequently analyzes and locates an attachment mechanism that is not mounted in place. It may be understood that, the identity information of the attachment mechanism may be an identity or mounting location identifier of the attachment mechanism.

In some embodiments, before step S31, the method further includes the following steps:
S38: Determine that communication authentication between the battery and the flight control system succeeds.

In this embodiment, before the unmanned aerial vehicle takes off, first, it is determined that communication authentication between the battery and the flight control system is successful, for example, models of the battery and the flight control system are successfully paired and communication connection is successful. On one hand, normal connection and adaption between the battery and the flight control system are ensured to ensure flight safety. On the other hand, it is ensured that the flight control system can receive instructions sent by the battery, to smoothly monitor the battery.

In some embodiments, the method further includes: detecting, by the battery, during flight of the unmanned aerial vehicle, whether the at least one attachment mechanism is in place; and sending, by the battery, a third signal to the flight control system in response to detecting that the at least one attachment mechanism is in place, wherein the third signal is configured to instruct the flight control system to maintain normal flight of the unmanned aerial vehicle; or sending, by the battery, a fourth signal to the flight control system in response to detecting that at least one of the at least one attachment mechanism is not in place, wherein the fourth signal is configured to instruct the flight control system to issue a fault prompt, wherein the fault prompt is configured to notify a user of a risk of the battery falling off.

In some embodiments, the fourth signal is further configured to instruct the flight control system to initiate a forced landing of the unmanned aerial vehicle.

In some embodiments, the flight control system is communicatively connected to a mobile terminal, and the fourth signal is further configured to instruct the flight control system to send the fault prompt to the mobile terminal to notify the user.

In some embodiments, the method further includes: storing fault information in response to detecting that at least one of the at least one attachment mechanism is not in place, wherein the fault information comprises identity information of the at least one attachment mechanism that is not in place.

In some embodiments, prior to detecting whether the at least one attachment mechanism is in place before the unmanned aerial vehicle takes off, the method further includes determining that communication authentication between the battery and the flight control system succeeds.

Based on the above, the battery is detachably mounted on the unmanned aerial vehicle by using at least one attachment mechanism. The battery is communicatively connected to a flight control system of the unmanned aerial vehicle. Before the unmanned aerial vehicle takes off, whether each attachment mechanism is in place is detected. A first signal is sent to the flight control system if each attachment mechanism is in place, the first signal being used for instructing the flight control system to initiate takeoff of the unmanned aerial vehicle. A second signal is sent to the flight control system if at least one attachment mechanism that is not in place is detected, the second signal being used for instructing the flight control system to prevent takeoff of the unmanned aerial vehicle. In other words, the battery is detachably mounted by using at least one attachment mechanism, so that the battery can be well fixed even if the attachment mechanism may have a problem that the attachment mechanism is not in place due to damage, aging or improper mounting. Before takeoff, each attachment mechanism is detected, and the unmanned aerial vehicle is controlled to normally take off when the attachment mechanism is in place, or otherwise, the takeoff is prohibited. In this way, a problem of battery falling off can be effectively monitored, accidents caused by battery falling off are avoided, and safety of the unmanned aerial vehicle is ensured.

In some embodiments, the signal monitor includes a first resistor, the first resistor and each attachment mechanism in the at least one attachment mechanism forming a first series circuit, the first series circuit is disrupted in response to determining that at least one of the at least one attachment mechanism is not in place; and a first terminal of the first series circuit is connected to a first terminal of the battery body, a second terminal of the first series circuit is connected to a second terminal of the battery body, a first terminal of the first resistor is connected to the first terminal of the first series circuit and a second terminal of the first resistor is connected to a first port of the processor.

In some embodiments, the signal monitor further includes a second resistor, a first terminal of the second resistor being connected to the second terminal of the first resistor and a second terminal of the second resistor being connected to the first port of the processor.

In some embodiments, the signal monitor includes a plurality of third resistors equal in number to attachment mechanisms, each third resistor and respective attachment mechanism forming a second series circuit, the second series circuit is disrupted in response to determining that at least one of the plurality of attachment mechanisms is not in place; and a first terminal of each second series circuit is connected to the first terminal of the battery body, a second terminal of each second series circuit is connected to the second terminal of the battery body, a first terminal of each third resistor is connected to a first terminal of a corresponding second series circuit and a second terminal of each third resistor is connected to a corresponding second port of the processor.

In some embodiments, the signal monitor further includes a plurality of fourth resistors equal in number to attachment mechanisms, a first terminal of one fourth resistor being connected to a second terminal of one third resistor and a second terminal of the fourth resistor being connected to a corresponding second port of the processor.

An embodiment of the present disclosure further provides a non-transitory computer-readable storage medium. The computer-readable storage medium stores computer executable instructions. When the computer executable instructions are executed by a processor, the processor is enabled to perform the battery monitoring method according to any of the foregoing embodiments.

The technical solutions provided by embodiments of the present disclosure can achieve the following advantages: the battery is detachably mounted by using at least one attachment mechanism piece, so that the battery can be well fixed even if the attachment mechanism piece may have a problem that the attachment mechanism piece cannot be mounted in place due to damage, aging or improper mounting. Before takeoff, each attachment mechanism piece is detected, and the unmanned aerial vehicle is controlled to normally take off when the attachment mechanism piece is mounted in place, or otherwise, the takeoff is prohibited. In this way, a problem of battery falling off can be effectively monitored, accidents caused by battery falling off are avoided, and safety of the unmanned aerial vehicle is ensured.

It is to be noted that, the foregoing described device embodiments are merely examples. The units described as separate parts may or may not be physically separate, and the parts displayed as units may or may not be physical units, may be located in one position, or may be distributed on a plurality of network units. Some or all of the modules may be selected based on an actual requirement, to achieve the objectives of the solutions of the embodiments.

Based on the descriptions of the foregoing implementations, a person of ordinary skill in the art may clearly understand that the implementations may be implemented by software in addition to a universal hardware platform, or by hardware. A person of ordinary skill in the art may understand that, all or some of the processes of the method in the foregoing embodiments may be implemented by a computer program instructing relevant hardware. The program may be stored in a non-transitory computer-readable storage medium. During execution of the program, the processes of the foregoing method embodiments may be included. The storage medium may be a magnetic disk, an optical disc, a read-only memory (ROM) or a random access memory (RAM).

Finally, it should be noted that the foregoing embodiments are merely used for describing the technical solutions of the present disclosure, but are not intended to limit the present disclosure. Under the ideas of the present disclosure, the technical features in the foregoing embodiments or different embodiments may also be combined, the steps may be performed in any order, and many other changes of different aspects of the present disclosure also exists as described above, and these changes are not provided in detail for simplicity. It should be understood by a person of ordinary skill in the art that although the present disclosure has been described in detail with reference to the foregoing embodiments, modifications can be made to the technical solutions described in the foregoing embodiments, or equivalent replacements can be made to some technical features in the technical solutions; and these modifications or replacements will not cause the essence of corresponding technical solutions to depart from the scope of the technical solutions in the embodiments of the present disclosure.

What is claimed is:

1. A battery monitoring method, comprising:
detecting, by a battery detachably mounted on an unmanned aerial vehicle via at least one attachment mechanism and communicatively connected to a flight control system of the unmanned aerial vehicle, before the unmanned aerial vehicle takes off, whether the at least one attachment mechanism is in place; and
sending, by the battery, a first signal to the flight control system in response to detecting that the at least one attachment mechanism is in place, wherein the first signal is configured to instruct the flight control system to initiate takeoff of the unmanned aerial vehicle; or
sending, by the battery, a second signal to the flight control system in response to detecting that at least one of the at least one attachment mechanism is not in place, wherein the second signal is configured to instruct the flight control system to prevent takeoff of the unmanned aerial vehicle.

2. The method according to claim 1, further comprising:
detecting, by the battery, during flight of the unmanned aerial vehicle, whether the at least one attachment mechanism is in place; and
sending, by the battery, a third signal to the flight control system in response to detecting that the at least one attachment mechanism is in place, wherein the third signal is configured to instruct the flight control system to maintain normal flight of the unmanned aerial vehicle; or
sending, by the battery, a fourth signal to the flight control system in response to detecting that at least one of the at least one attachment mechanism is not in place, wherein the fourth signal is configured to instruct the flight control system to issue a fault prompt, wherein the fault prompt is configured to notify a user of a risk of the battery falling off.

3. The method according to claim 2, wherein the fourth signal is further configured to instruct the flight control system to initiate a forced landing of the unmanned aerial vehicle.

4. The method according to claim 2, wherein the flight control system is communicatively connected to a mobile terminal, and the fourth signal is further configured to instruct the flight control system to send the fault prompt to the mobile terminal to notify the user.

5. The method according to claim 1, further comprising:
storing fault information in response to detecting that at least one of the at least one attachment mechanism is not in place, wherein the fault information comprises identity information of the at least one attachment mechanism that is not in place.

6. The method according to claim 5, further comprising:
determining, prior to detecting whether the at least one attachment mechanism is in place before the unmanned aerial vehicle takes off, that communication authentication between the battery and the flight control system succeeds.

7. A battery, comprising:
a battery body;
a signal monitor, connected to the battery body, wherein the signal monitor is configured to obtain a mount signal of at least one attachment mechanism, wherein the at least one attachment mechanism is configured to detachably mount the battery on an unmanned aerial vehicle, wherein the mount signal is configured to indicate whether the at least one attachment mechanism is in place;
a processor, respectively connected to the signal monitor and the battery body, wherein the processor is configured to be communicatively connected to a flight control system of the unmanned aerial vehicle; and
a memory, connected to the processor, wherein the memory stores instructions executable by the processor;
wherein the processor is configured to perform acts comprising:
detecting, before the unmanned aerial vehicle takes off, whether the at least one attachment mechanism is in place; and
sending a first signal to the flight control system in response to detecting that the at least one attachment mechanism is in place, wherein the first signal is configured to instruct the flight control system to initiate takeoff of the unmanned aerial vehicle; or
sending a second signal to the flight control system in response to detecting that at least one of the at least one attachment mechanism is not in place, wherein the second signal is configured to instruct the flight control system to prevent takeoff of the unmanned aerial vehicle.

8. The battery according to claim 7, wherein the signal monitor comprises:
a first resistor, wherein the first resistor and the at least one attachment mechanism form a first series circuit, wherein the first series circuit is disrupted in response to determining that at least one of the at least one attachment mechanism is not in place;
wherein a first terminal of the first series circuit is connected to a first terminal of the battery body, a second terminal of the first series circuit is connected to a second terminal of the battery body, a first terminal of the first resistor is connected to the first terminal of the first series circuit and a second terminal of the first resistor is connected to a first port of the processor.

9. The battery according to claim 8, wherein the signal monitor further comprises:
a second resistor, wherein a first terminal of the second resistor is connected to the second terminal of the first resistor and a second terminal of the second resistor is connected to the first port of the processor.

10. The battery according to claim 7, wherein the signal monitor comprises:
a plurality of third resistors, equal in number to a plurality of attachment mechanisms, wherein at least one third resistor respectively forms a second series circuit with at least one attachment mechanism, wherein the second series circuit is disrupted in response to determining that at least one of the plurality of attachment mechanisms is not in place;
wherein a first terminal of the second series circuit is connected to the first terminal of the battery body, a second terminal of the second series circuit is connected to the second terminal of the battery body, a first terminal of the third resistor is connected to a first terminal of a corresponding second series circuit and a second terminal of the third resistor is connected to a corresponding second port of the processor.

11. The battery according to claim 8, wherein the signal monitor further comprises:
a plurality of fourth resistors, equal in number to a plurality of attachment mechanisms, wherein a first terminal of the fourth resistor is connected to a second terminal of a corresponding third resistor and a second terminal of the fourth resistor is connected to a corresponding second port of the processor.

12. An unmanned aerial vehicle, comprising:
a flight control system;
a battery, wherein the battery is communicatively connected to the flight control system, and the battery is detachably mounted on the unmanned aerial vehicle by at least one attachment mechanism;
wherein the battery further comprising:
a battery body;
a signal monitor, connected to the battery body, wherein the signal monitor is configured to obtain a mount signal of at least one attachment mechanism, wherein the at least one attachment mechanism is configured to detachably mount the battery on an unmanned aerial vehicle, wherein the mount signal is configured to indicate whether the at least one attachment mechanism is in place;
a processor, respectively connected to the signal monitor and the battery body, wherein the processor is configured to be communicatively connected to a flight control system of the unmanned aerial vehicle; and
a memory, connected to the processor, wherein the memory stores instructions executable by the processor;
wherein the processor is configured to perform acts comprising:
detecting, before the unmanned aerial vehicle takes off, whether the at least one attachment mechanism is in place; and
sending a first signal to the flight control system in response to detecting that the at least one attachment mechanism is in place, wherein the first signal is configured to instruct the flight control system to initiate takeoff of the unmanned aerial vehicle; or
sending a second signal to the flight control system in response to detecting that at least one of the at least one attachment mechanism is not in place, wherein the second signal is configured to instruct the flight control system to prevent takeoff of the unmanned aerial vehicle.

13. The unmanned aerial vehicle according to claim 12, wherein the signal monitor comprises:
a first resistor, wherein the first resistor and the at least one attachment mechanism form a first series circuit, wherein the first series circuit is disrupted in response to determining that at least one of the at least one attachment mechanism is not in place;
wherein a first terminal of the first series circuit is connected to a first terminal of the battery body, a second terminal of the first series circuit is connected to a second terminal of the battery body, a first terminal of the first resistor is connected to the first terminal of the first series circuit and a second terminal of the first resistor is connected to a first port of the processor.

14. The unmanned aerial vehicle according to claim 13, wherein the signal monitor further comprises:
a second resistor, wherein a first terminal of the second resistor is connected to the second terminal of the first resistor and a second terminal of the second resistor is connected to the first port of the processor.

15. The unmanned aerial vehicle according to claim 13, wherein the signal monitor comprises:
a plurality of third resistors, equal in number to a plurality of attachment mechanisms, wherein at least one third resistor respectively forms a second series circuit with at least one attachment mechanism, wherein the second series circuit is disrupted in response to determining that at least one of the plurality of attachment mechanisms is not in place;
wherein a first terminal of the second series circuit is connected to the first terminal of the battery body, a second terminal of the second series circuit is connected to the second terminal of the battery body, a first terminal of the third resistor is connected to a first terminal of a corresponding second series circuit and a second terminal of the third resistor is connected to a corresponding second port of the processor.

16. The unmanned aerial vehicle according to claim 13, herein the signal monitor further comprises:
a plurality of fourth resistors, equal in number to a plurality of attachment mechanisms, wherein a first terminal of the fourth resistor is connected to a second terminal of a corresponding third resistor and a second terminal of the fourth resistor is connected to a corresponding second port of the processor.

17. The unmanned aerial vehicle according to claim 12, wherein the processor is further configured to perform acts comprising:
detecting, during flight of the unmanned aerial vehicle, whether the at least one attachment mechanism is in place; and
sending a third signal to the flight control system in response to detecting that the at least one attachment mechanism is in place, wherein the third signal is configured to instruct the flight control system to maintain normal flight of the unmanned aerial vehicle; or
sending a fourth signal to the flight control system in response to detecting that at least one of the at least one attachment mechanism is not in place, wherein the fourth signal is configured to instruct the flight control system to issue a fault prompt, wherein the fault prompt is configured to notify a user of a risk of the battery falling off.

18. The unmanned aerial vehicle according to claim 17, wherein the fourth signal is further configured to instruct the flight control system to initiate a forced landing of the unmanned aerial vehicle.

19. The unmanned aerial vehicle according to claim 17, wherein the flight control system is communicatively connected to a mobile terminal, and the fourth signal is further configured to instruct the flight control system to send the fault prompt to the mobile terminal to notify the user.

20. The unmanned aerial vehicle according to claim 12, wherein the processor is further configured to perform:
storing fault information in response to detecting that at least one of the at least one attachment mechanism is not in place, wherein the fault information comprises identity information of the attachment mechanism that is not in place.
